(19) United States
(12) Patent Application Publication
(10) Pub. No.: US 2024/0234510 A9
(43) Pub. Date: Jul. 11, 2024

(54) SiC MOSFET POWER SEMICONDUCTOR DEVICE AND METHOD OF MANUFACTURING SAME

(71) Applicant: DB HiTek Co., Ltd., Bucheon-si (KR)

(72) Inventors: Hee Bae LEE, Bucheon-si (KR); Jae Yuhn MOON, Bucheon-si (KR); Seung Hyun KIM, Bucheon-si (KR)

(21) Appl. No.: 18/304,414

(22) Filed: Apr. 21, 2023

(30) Foreign Application Priority Data
Oct. 19, 2022 (KR) 10-2022-0134680

(51) Int. Cl. H01L 29/16; H01L 29/06; H01L 29/423; H01L 29/66; H01L 29/78

(52) U.S. Cl. CPC H01L 29/1608; H01L 29/0696; H01L 29/4236; H01L 29/66068; H01L 29/66734; H01L 29/7813

(57) ABSTRACT

Disclosed are a SiC MOSFET power semiconductor device and a method of manufacturing the same. More particularly, a SiC MOSFET power semiconductor device and a method of manufacturing the same are disclosed, including a trench gate having a hexagonal shape in a plan or layout view, to improve on-resistance (Rsp) characteristics and increase channel density.

### CROSS REFERENCE TO RELATED APPLICATION

The present application claims priority to Korean Patent Application No. 10-2022-0134680, filed Oct. 19, 2022, the entire contents of which are incorporated herein for all purposes by this reference.

### BACKGROUND OF THE INVENTION

### Field of the Invention

The present disclosure relates generally to a SiC MOSFET power semiconductor device and a method of manufacturing the same. More particularly, the present disclosure relates to a SiC MOSFET power semiconductor device and a method of manufacturing the same, including a trench gate has a hexagonal shape to improve on-resistance (Rsp) characteristics due to an increase in channel density.

### Description of the Related Art

Silicon carbide (SiC) is a material having a wider energy bandgap, a higher dielectric field, a higher saturated electron drift velocity, and higher thermal conductivity than silicon. Due to these excellent properties, SiC is attracting attention as a semiconductor material for high-temperature and high-voltage devices.

SiC-based MOSFET devices are presently transitioning from a planar type to a trench type in order to secure on-resistance characteristics. The trench-type SiC MOSFET can dramatically reduce the device pitch and improve the on-resistance. Despite these advantages, a problem remains that a strong electric field may be applied to a gate oxide film below a gate electrode.

In more detail, in a conventional SiC MOSFET power semiconductor device, a trench gate including a gate oxide film and a gate electrode generally has a rectangular shape (e.g., in a plan or layout view). In such a conventional device structure, in order to disperse a strong electric field applied to the gate oxide film, a source trench structure is used, or a structure that does not include a source, so that a channel region forms only on one side of the trench gate. However, this is not an ultimate solution to the problem caused by a maximum E-field applied to the gate oxide film. In addition, since the area of the channel region is relatively small in the same area of the device, the channel density is inevitably relatively low.

The foregoing is intended merely to aid in the understanding of the background of the present disclosure, and is not intended to mean that the present disclosure falls within the purview of the related art that is already known to those skilled in the art.

### DOCUMENT OF RELATED ART

Korean Patent No. 10-1896332, entitled “SEMICONDUCTOR DEVICE AND METHOD MANUFACTURING THE SAME.”

### SUMMARY OF THE INVENTION

Accordingly, the present disclosure has been made keeping in mind the above problems occurring in the related art, and an objective of the present disclosure is to provide a SiC MOSFET power semiconductor device and a method of manufacturing the same, in which a trench gate has a hexagonal shape (e.g., in a plan or layout view) and a honeycomb structure to improve on-resistance characteristics due to an increase in channel density.

Another objective of the present disclosure is to provide a SiC MOSFET power semiconductor device and a method of manufacturing the same, including a source in contact with a gate region and a shield region that may cross each other in a unit cell to ensure reliability and reduce a maximum E-field applied to a gate oxide film.

Still another objective of the present disclosure is to provide a SiC MOSFET power semiconductor device and a method of manufacturing the same, including adjacent unit cells with the same cross-section between the centers thereof to increase ease of manufacturing.

Yet another objective of the present disclosure is to provide a SiC MOSFET power semiconductor device and a method of manufacturing the same, comprising unit cells inn columns, where the unit cells of an mth column may be non-channel-forming regions, and the unit cells of an m−1th and/or m+1th column are channel-forming regions, to reduce the electric field applied to the gate oxide film.

In order to achieve the above objectives, according to one aspect of the present disclosure, there is provided a SiC MOSFET power semiconductor device including: a substrate; a lightly doped second conductivity type drift region on the substrate; a first conductivity type well in the drift region; a heavily doped second conductivity type source in a surface of the well; a trench gate region having an upper surface substantially coplanar with a surface of the well or the source, and a lowermost surface in the drift region; and a heavily doped first conductivity type shield region having an upper surface substantially coplanar with the surface of the well and a lowermost surface in the drift region.

According to another aspect of the present disclosure, the lowermost surface of the shield region may be located lower than the lowermost surface of the gate region.

According to another aspect of the present disclosure, the shield region may be in contact with a sidewall of the gate region and is in partial contact with the lowermost surface of the gate region.

According to another aspect of the present disclosure, the gate region may have a hexagonal shape and a honeycomb structure.

According to another aspect of the present disclosure, the SiC MOSFET power semiconductor device may further include an ohmic contact on the shield region and the source.

According to another aspect of the present disclosure, there is provided a SiC MOSFET power semiconductor device including: a substrate; a lightly doped second conductivity type drift region on the substrate; a trench gate region having a lowermost surface in the drift region, a hexagonal shape (e.g., in a plan or layout view), and a honeycomb structure, and separating a plurality of unit cells of substantially the same area; a heavily doped second conductivity type source in contact with the trench gate region and in each of the unit cells; and a heavily doped first conductivity type shield region having a lowermost surface in the drift region lower than the lowermost surface of the trench gate region, wherein the source and the shield region in each of the unit cells may alternate along a hexagonal path around a center of the unit cell at a position a predetermined distance from the center.

According to another aspect of the present disclosure, each of the unit cells may comprise a plurality of the sources, and the plurality of the sources may be in contact with every other surface of the trench gate region.

According to another aspect of the present disclosure, the plurality of the sources may not be continuously in contact with adjacent surfaces of the trench gate region in each of the unit cells.

According to another aspect of the present disclosure, the SiC MOSFET power semiconductor device may further include: a first conductivity type well below the source and in or on the drift region; an insulating film on the trench gate region; and an ohmic contact on the source and the shield region.

According to another aspect of the present disclosure, in each of the unit cells, the source and the shield region may alternate along the hexagonal path around the center of the unit cell at a position spaced from the center by a distance smaller than a distance from the center to the trench gate region.

According to another aspect of the present disclosure, in each of the unit cells, the source and the shield region may not alternate around the center of the unit cell at a position adjacent to the center.

According to another aspect of the present disclosure, the shield region may be in contact with at least part of a lower portion of an adjacent gate region.

According to another aspect of the present disclosure, each pair of adjacent unit cells may have the same cross-section between centers thereof.

According to another aspect of the present disclosure, there is provided a SiC MOSFET power semiconductor device including: a substrate; a lightly doped second conductivity type drift region on the substrate; and a trench gate region of a trench structure having a lowermost surface in the drift region, the trench gate region having a hexagonal shape and a honeycomb structure and separating a plurality of unit cells into n columns, wherein the unit cells of an mth column may be non-channel-forming regions, and the unit cells of an m−1th and/or m+1th column may be channel formed regions.

According to another aspect of the present disclosure, each of the unit cells of the mth column may include: a first heavily doped second conductivity type source spaced apart from an adjacent gate region; and a first heavily doped first conductivity type shield region between the first source and the adjacent gate region.

According to another aspect of the present disclosure, each of the unit cells of the m−1th and/or m+1th column may include: a second heavily doped first conductivity type shield region spaced apart from an adjacent gate region; and a second source between the second shield region and the adjacent gate region, the second source being a heavily doped second conductivity type impurity region.

According to another aspect of the present disclosure, the first source may have a hexagonal shape, and the first shield region may have a hexagonal shape.

According to another aspect of the present disclosure, there is a method of manufacturing a SiC MOSFET power semiconductor device, the method including: forming a drift region on a substrate; forming a shield region in a surface of the drift region; forming a source in the surface of the drift region; forming a trench in the surface of the drift region; forming a gate oxide film in the trench and forming a gate electrode on the gate oxide film and filling the trench; forming an insulating film on the gate electrode; and forming an ohmic contact on the source and the shield region, wherein the trench may have a lowermost surface higher than a lowermost surface of the shield region and a honeycomb structure with a hexagonal shape, and the trench separates a plurality of unit cells.

According to another aspect of the present disclosure, the source and the shield region in each of the unit cells may alternate along a hexagonal path around a center of the unit cell at a position a predetermined distance from the center.

According to another aspect of the present disclosure, the trench may separate the unit cells into n columns, the unit cells of an mth column may be non-channel-forming regions, and the unit cells of an m−1th and/or m+1th column may be channel-forming regions.

The present disclosure has the following effects by the above configuration.

By forming or providing the trench gate with a hexagonal shape and a honeycomb structure, on-resistance characteristics can improve due to an increase in channel density.

In addition, by forming or including the source in contact with the trench gate region and the shield region to cross each other in the unit cell, reliability can be ensured by reducing a maximum E-field applied to a gate oxide film.

In addition, by providing each arbitrary pair of adjacent unit cell regions with the same cross-section between the centers thereof, ease of manufacturing can be increased.

In addition, in the unit cells separated into n columns, by configuring the unit cell regions of the mth column as the non-channel-forming regions and the unit cell regions of the m−1th and/or m+1th as the channel-forming regions, an electric field applied to the gate oxide film can be reduced.

Meanwhile, the effects of the present disclosure are not limited to those described above and other effects not stated directly could be understood from the following description and claims.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a plan or layout view illustrating a SiC MOSFET power semiconductor device according to a first embodiment of the present disclosure;

FIG. 2 is a cross-sectional view illustrating the SiC MOSFET power semiconductor device illustrated in FIG. 1, taken along line A-A′;

FIG. 3 is a plan or layout view illustrating only gates, sources, and shield regions in the SiC MOSFET power semiconductor device illustrated in FIG. 1;

FIG. 4 is a plan or layout view illustrating only the gate regions, wells, and ohmic contacts in the SiC MOSFET power semiconductor device illustrated in FIG. 1;

FIG. 5 is a plan or layout view illustrating a SiC MOSFET power semiconductor device according to a second embodiment of the present disclosure;

FIG. 6 is a cross-sectional view illustrating the SiC MOSFET power semiconductor device illustrated in FIG. 5, taken along line B-B′;

FIG. 7 is a plan or layout view illustrating only gate regions, sources, and shield regions in the SiC MOSFET power semiconductor device illustrated in FIG. 6;

FIG. 8 is a plan or layout view illustrating only the gate regions, wells, and ohmic contacts in the SiC MOSFET power semiconductor device illustrated in FIG. 6; and

FIGS. 9 to 17 are cross-sectional views illustrating a method of manufacturing a SiC MOSFET power semiconductor device according to an embodiment of the present disclosure.

### DETAILED DESCRIPTION OF THE INVENTION

Hereinafter, exemplary embodiments of the present disclosure will be described in more detail with reference to the accompanying drawings. The embodiments of the present disclosure can be modified in various forms. Therefore, the scope of the present disclosure should not be construed as being limited to the following embodiments, but should be construed on the basis of the descriptions in the appended claims. The embodiments of the present disclosure are provided for complete disclosure of the present disclosure and to fully convey the scope of the present disclosure to those ordinarily skilled in the att.

As used herein, the singular forms are intended to include the plural forms as well, unless the context clearly indicates otherwise. It will be further understood that the terms “comprise” and/or “comprising”, etc. when used in this specification, specify the presence of stated features, integers, steps, operations, elements, components, and/or combinations of them but do not preclude the presence or addition of one or more other features, integers, steps, operations, elements, components, and/or combinations thereof.

As used herein, when an element (or layer) is referred to as being disposed on another element (or layer), it can be disposed directly on the other element, or intervening element(s) (or layer(s)) may be disposed therebetween. In contrast, when an element is referred to as being directly disposed on or above another component, intervening element(s) are not located therebetween. Further, the terms “on”, “above”, “below”, “upper”, “lower”, “one side”, “side surface”, etc. are used to describe one element's relationship to one or more other element(s) illustrated in the drawings.

Meanwhile, when an embodiment can be implemented differently, functions or operations described in a particular block may occur in a different way from a flow described herein. For example, two consecutive blocks may be performed simultaneously, or the blocks may be performed in reverse according to related functions or operations.

Hereinafter, it will be understood that a first conductivity type impurity region is a “P-type” doped region, and a second conductivity type impurity region is an “N-type” doped region. Alternatively, in some cases, the first conductivity type impurity region may be an “N-type” region and the second conductivity type impurity region may be a “P-type” doped region, but the present disclosure not limited thereto.

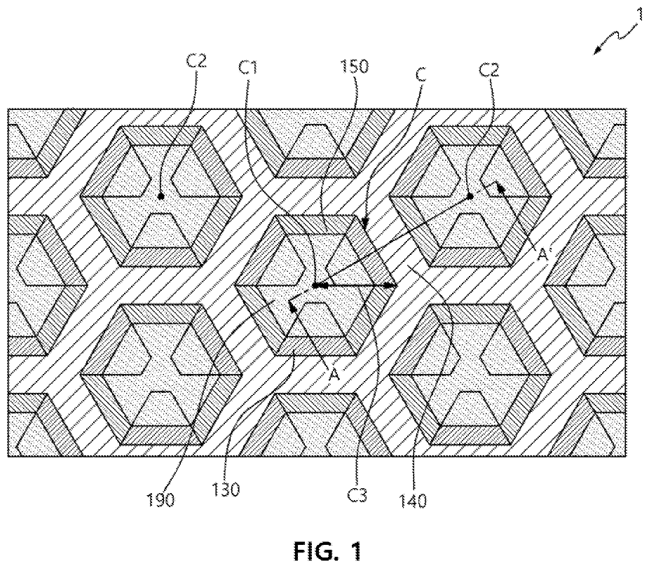

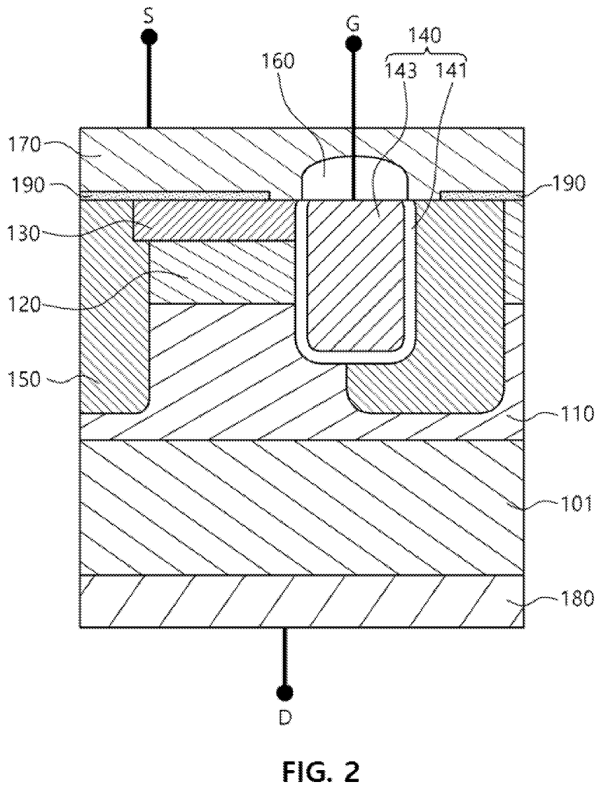

FIG. 1 is a plan or layout view illustrating a SiC MOSFET power semiconductor device 1 according to a first embodiment of the present disclosure; and FIG. 2 is a cross-sectional view illustrating the SiC MOSFET power semiconductor device 1 illustrated in FIG. 1, taken along line A-A′.

Hereinafter, the SiC MOSFET power semiconductor device 1 according to the first embodiment of the present disclosure will be described in detail with reference to the accompanying drawings.

Referring to FIGS. 1 and 2, the present disclosure relates generally to a SiC MOSFET power semiconductor device 1. More particularly, the present disclosure relates to the SiC MOSFET power semiconductor device 1, in which a trench gate has a hexagonal shape to improve on-resistance (Rsp) characteristics due to an increase in channel density.

In the device 1, a substrate 101 may include, for example, a silicon carbide (SiC) wafer heavily doped with a second conductivity type impurity. In more detail, the substrate 101 may comprise, for example, a 4H-SiC or 6H-SiC substrate. The heavily doped substrate 101 may include, but is not limited to, for example, phosphorus as the second conductivity type impurity.

A drift region 110 may be on the substrate 101. The drift region 110 may include, for example, a SiC epitaxial layer grown on the SiC single crystal substrate 101 while maintaining a specific crystal orientation relationship with the crystal direction or lattice of the substrate 101. In addition, the drift region 110 may include a lightly doped second conductivity type impurity region having a lower doping concentration than the substrate 101. The second conductivity type impurity may include, but is not limited to, for example.

A well 120 may be in the drift region 110 and optionally at a surface of the drift region 110. The well 120 may comprise a first conductivity type doped impurity region. In addition, a source 130 may be in the well 120 and at a surface of the well 120. The source 130 may comprise a heavily doped second conductivity type impurity region. Here, the source 130 may have a higher doping concentration than the drift region 110. In addition, the source 130 may be in the well 120 at a position in contact with a gate region 140 which will be described later. Thus, a channel region may be formed along the interface between the source 130 and the gate region 140. Here, the source 130 may be in contact with opposite sidewalls of the gate region 140 or in contact with only one sidewall thereof as illustrated. That is, the source 130 may be on the left or right side of the gate region 140 or on both sides in a cross-sectional view, but the present disclosure is not limited thereto. An ohmic contact 190 may be on the source 130. The ohmic contact 190 may include, but is not limited to, Ti or TiN.

In addition, the gate region 140 may be in the drift region 110. The gate region 140 may have a trench structure and may extend from the well 120 or the source 130 to the drift region 110. The gate region 140 may have a shallower depth than a shield region 150 which will be described later. That is, a lowermost surface of the gate region 140 may be more distant from the substrate 101 than a lowermost surface of the shield region 150.

The gate region 140 may be in a trench, and may include a gate oxide film 141 along an inner surface of the trench, and a gate electrode 143 on the gate oxide film 141 filling the trench. Thus, an outer surface of the gate oxide film 141 may be in contact with the drift region 110, the well 120, and the source 130. The gate electrode 143 may comprise, for example, polysilicon doped with an impurity, and may be on the gate oxide layer 141 and filling the trench. In addition, the gate region 140 may have a hexagonal shape in a plan or layout view, rather than a stripe or rectangular shape, and a detailed description thereof will be described later.

Next, the shield region 150 may be in the drift region 110 (and at a surface thereof) or the well 120. The channel region may not be in the shield region 150. The shield region 150 may extend from an uppermost surface of the SiC epitaxial layer and/or the well 120, and may have a depth greater than that of the gate region 140. A lower portion of the shield region 150 may be in the drift region 110. In addition, the shield region 150 may comprise a heavily doped first conductivity type impurity region, and preferably has a higher doping concentration than the well 120. In addition, the shield region 150 may be at a position where the lower portion thereof at least partially overlaps a lower portion (or is deeper than a lowermost surface) of the gate region 140. Here, it is preferable that the shield region 150 does not completely cover or surround the lower portion or the lowermost surface of the gate region 140. That is, the shield region 150 is preferably in contact with part of the lower portion of the gate region 140.

For example, the shield region 150 may be in contact with a sidewall of an adjacent gate region 140 and also in contact with part of a lowermost surface of the adjacent gate region 140. The shield region 150 may be between the drift region 110 and the gate oxide film 141 to prevent latch-up. With this structure, a maximum E-field may form in the shield region 150 below the gate oxide film 141 so that an avalanche current flows through a path formed by the shield region 150 below the gate oxide film 141, the shield region 150 on the sidewall of the gate oxide film 141, and a source metal or source electrode 170 which will be described later. An ohmic contact 190 may be on the shield region 150. The ohmic contact 190 may include, but is not limited to, Ti or TiN.

An insulating film 160 may be on the gate region 140. The insulating film 160 may cover the gate electrode 143. For example, the insulating film 160 may be or include an oxide film, such as silicon dioxide. In addition, the source metal or source electrode 170 may be formed on the drift region 110. The source metal 170 may cover the source 130, the shield region 150, and the insulating film 160. The source metal 170 may include, but is not limited to, Al or a conductive Al alloy. The source metal 170 may be electrically connected to a source terminal S. In addition, the gate electrode 143 may be electrically connected to a gate terminal G through a contact hole in the insulating film 160.

In addition, a drain metal or drain electrode 180 may be formed under the substrate 101. The drain metal 180 may be electrically connected to a drain terminal D. The drain metal 180 may include, but is not limited to, Ni or Ag.

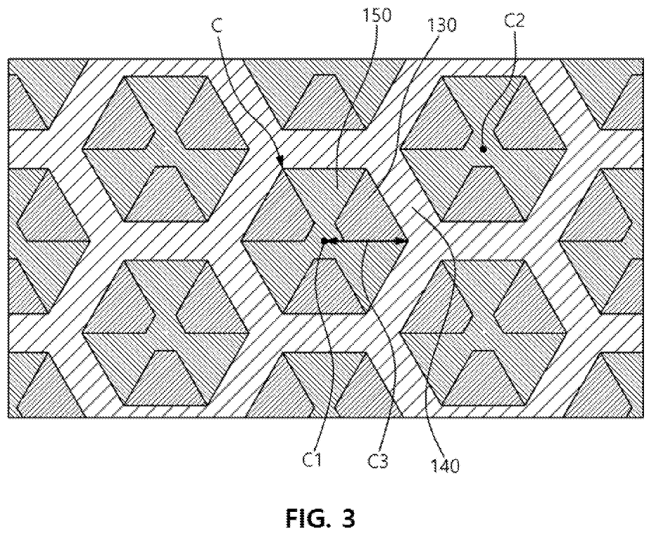

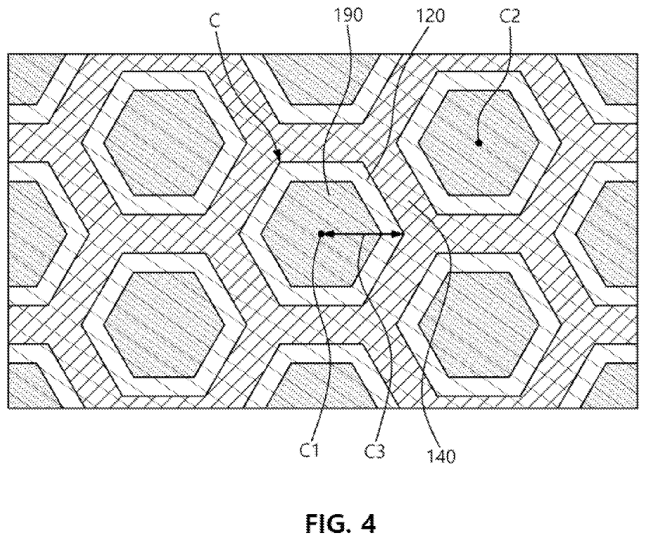

FIG. 3 is a plan or layout view illustrating only gate regions 140, sources 130, and shield regions 150 in the SiC MOSFET power semiconductor device 1 illustrated in FIG. 1; and FIG. 4 is a plan or layout view illustrating only the gate regions 140, wells 120, and ohmic contacts 190 in the SiC MOSFET power semiconductor device 1 illustrated in FIG. 1.

Hereinafter, the problems of a conventional SiC MOSFET power semiconductor device and the structure of the SiC MOSFET power semiconductor device 1 according to the first embodiment of the present disclosure for solving the problems will be described in more detail.

In the conventional SiC MOSFET power semiconductor device, a trench gate including a gate oxide film and a gate electrode generally has a rectangular shape (e.g., in a plan or layout view). In such a conventional device structure, in order to disperse a strong electric field applied to the gate oxide film, a source trench structure is used, or a structure that does not include a source, so that a channel region forms only on one side of the trench gate. However, this is not an ultimate solution to the problem caused by a maximum E-field applied to the gate oxide film. In addition, since the area of the channel region is relatively small in the same area of the device, the channel density is inevitably relatively low.

In order to overcome the above problems, referring to FIGS. 1 to 4, the SiC MOSFET power semiconductor device 1 according to the first embodiment of the present disclosure includes a gate region 140 having a trench structure with a hexagonal shape (e.g., in a plan or layout view). Here, a plurality of hexagonal gates 140 may be present, and the plurality of hexagonal gates 140 may be in a honeycomb pattern, for example, as shown in FIG. 1. With this structure, there may be no loss of space, and area utilization (e.g., percentage of layout area dedicated to the trench gates) may increase relative to the conventional SiC power semiconductor device having rectangular trench gates. Hereinafter, a single gate 140 having a hexagonal shape and a region inside the gate 140 will be referred to as a unit cell C. That is, an arrangement of the unit cells C may have a honeycomb structure.

In the SiC MOSFET power semiconductor device 1 according to the first embodiment of the present disclosure, a plurality of unit cells C may be in contact with or adjacent to each other. For example, an arbitrary hexagonal unit cell C may have six surfaces of in contact with or adjacent to six other unit cells C. Here, it is preferable that the distances from a center C1 of the arbitrary unit cell C to centers C2 of the adjacent or contacting unit cells C are substantially the same, within an error range (e.g., manufacturing margins).

Hereinafter, the arbitrary unit cell C will be described in detail.

In the unit cell C, the gate region 140 having a trench structure may have a hexagonal shape. As described above, the gate region 140 may include the gate oxide film 141 along the inner surface of the trench, and the gate electrode 143 on the gate oxide film 141 and filling the trench.

In addition, the source 130 and the shield region 150 may cross each other in or near the gate region 140. The term “cross” may mean, for example, that the source 130 and the shield region 150 alternate along a hexagonal path around the center C1 at a position spaced a predetermined distance from the center C1 of the unit cell C in or near the gate region 140. Here, the “predetermined distance from the center C1 of the unit cell C in or near the gate region 140” may be smaller than a distance C3 from the center C1 of the unit cell C to an adjacent gate region 140.

In more detail, the source 130 and the shield region 150 may alternate along the hexagonal path around the center C (e.g., at or near [but within] the periphery of the unit cell C) depending on the distance (e.g., C4<C3) from the center C1 of the unit cell C in or near the gate region 140. When the value of C4 is close to the value of C3, the source 130 and the shield region 150 may alternate along the hexagonal path since the channel region forms where the gate region 140 and the source 130 are in contact with each other. In addition, when the value of C4 is close to the value of C1, the source 130 and the shield region 150 may or may not alternate along the hexagonal path. This arrangement may vary depending on the shape of the source 130 in a plan or layout view.

For example, a plurality of sources 130 may be physically independent of each other within the unit cell C, and preferably, a hexagonal unit cell C includes three sources 130 spaced apart from each other and in contact with arbitrary sidewall surfaces of the gate region 140. Here, it is preferable that the three sources 130 are in contact with three sidewall surfaces out of six sidewall surfaces of the gate region 140, and are not continuously in contact with a pair of immediately adjacent sidewall surfaces of the gate region 140. Here, the shield region 150 may be where the sources 130 are not (e.g., in the layout or plan view of the uppermost surface of the SiC epitaxial layer). It should be noted, however, that the present disclosure is not limited to the examples described above.

On the contrary, three sources 130 may be in contact with three sidewall surfaces of the gate region 140 and have sides in contact with each other. For example, a plurality of sources 130 may be in contact with each other at the center C1 of the unit cell C or at a position adjacent thereto. However, the present disclosure is not limited thereto, as long as the sources 130 and the shield regions 150 alternate along the hexagonal path around the center C1 at the predetermined distance C4 from the center C1 of the unit cell C in or near the gate region 140.

In addition, the well 120 may be below the source 130 and in or on the drift region 110. In addition, the insulating film 160 may be on the gate region 140. The source metal or source electrode 170 may entirely cover an upper surface of the drift region 110 or the substrate 101. Here, the source metal 170 may be on the source 130, the shield region 150, and the ohmic contact 190.

With such a structure, current may flow in the source 130, forming the channel region, and the alternating channel regions and shield regions 150 may be advantageous in terms of electric field distribution. Also, the channel density may increase in the same area of the device, and thus, on-resistance (Rsp) characteristics may improve. That is, in order to achieve electric field distribution, the plurality of unit cells C in a honeycomb pattern may compensate for loss of space where there is no channel region.

It is preferable that the cross-section between the center C1 of the arbitrary unit cell C and the center C2 of each adjacent unit cell C is substantially the same.

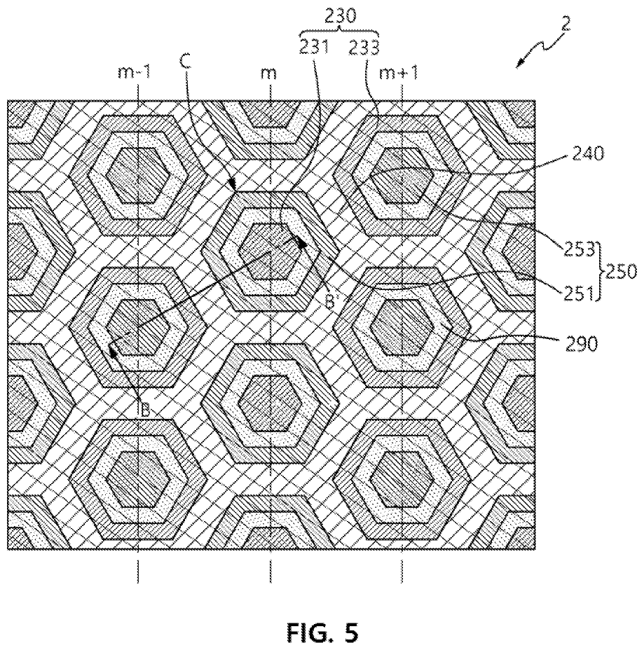

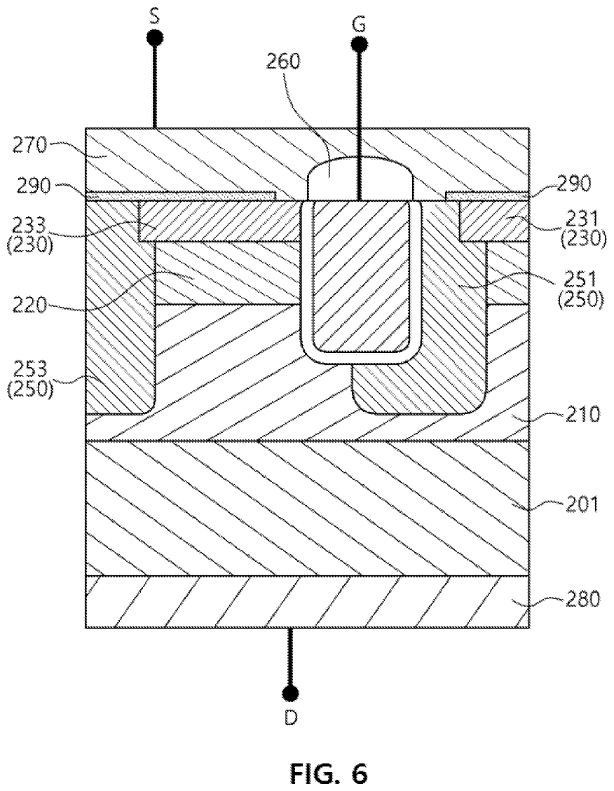

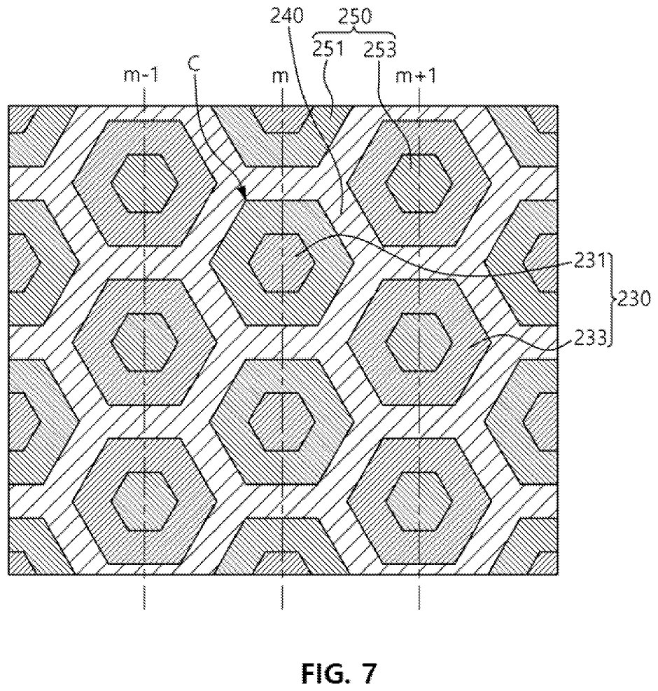

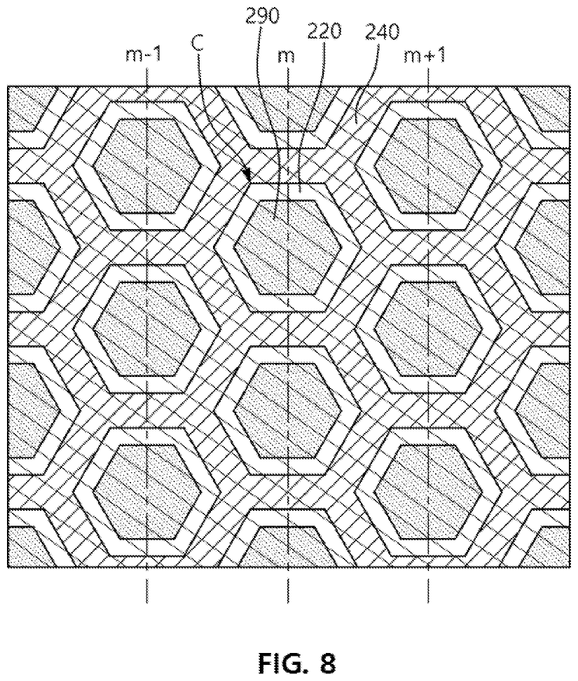

FIG. 5 is a plan or layout view illustrating a SiC MOSFET power semiconductor device 2 according to a second embodiment of the present disclosure; FIG. 6 is a cross-sectional view illustrating the SiC MOSFET power semiconductor device 2 illustrated in FIG. 5, taken along line B-B′; FIG. 7 is a plan or layout view illustrating only gate regions 240, sources 230, and shield regions 250 in the SiC MOSFET power semiconductor device illustrated in FIG. 6; and FIG. 8 is a plan or layout view illustrating only the gate regions, wells, and ohmic contacts in the SiC MOSFET power semiconductor device illustrated in FIG. 6.

Hereinafter, the SiC MOSFET power semiconductor device 2 according to the second embodiment of the present disclosure will be described in detail with reference to the accompanying drawings.

Referring to FIGS. 5 to 8, the device 2 according to the second embodiment includes the same components as those of the device 1 according to the first embodiment. In the drawings, the components that overlap or are the same as those of the first embodiment are denoted by reference numeral “2xx” instead of reference numeral “1xx”. In addition, the B-B′ cross-sectional view of the device 2 according to the second embodiment is substantially the same as or similar to the A-A′ cross-sectional view of the device 1 according to the first embodiment, so a redundant description thereof will be omitted.

Referring to FIGS. 5 to 8, in a unit cell C of the device 2, a gate region 240 having a trench structure may have a hexagonal shape in the plan or layout view. As described above, the gate region 240 may include a gate oxide film 241 along an inner surface of the trench, and a gate electrode 243 on the gate oxide film 241 and filling the trench. A plurality of the gate regions 240 may be in a honeycomb pattern or arrangement. That is, in the SiC MOSFET power semiconductor device 2 according to the second embodiment of the present disclosure, a plurality of unit cells C may be contact with each other or with a common gate region 240 having the honeycomb pattern. For example, six sidewall surfaces of an arbitrary unit cell C may be in contact with six other unit cells C or with six sidewall surfaces of the gate region 240. Here, it is preferable that the distances from a center C1 of the arbitrary unit cell C to centers C2 of six adjacent unit cells C are substantially the same (e.g., within an error range).

With such a structure, the unit cells C may form a plurality of columns. That is, n columns of unit cells C may be in the device 2. Here, in the unit cells C of a specific mth (0<m<n) column, the source 230 may have, for example, a hexagonal shape in each of the unit cells C (e.g., in a plan or layout view). The source 230 may be at a center C1 of each of the unit cells C and may be spaced apart from a gate region 240. A shield region 250 may be between the source 230 and the gate region 240 surrounding the source 230. For convenience of description, the source 230 in the mth column is referred to as a “first source 231” and the shield region 250 is referred to as a “first shield region 251”. In the mth column, the first shield region 251 may have, for example, a hexagonal shape in the plan or layout view and may be in contact with the gate region 240, and the first source 231 having, for example, a hexagonal shape may be in the first shield region 251. That is, the first shield region 251 may surround the first source 231. With this structure, a channel region may not be in the unit cells C of the mth column. However, the first source 231 is not limited to a hexagonal shape, and it is sufficient as long as it is spaced apart from the adjacent gate region 240. In addition, the shape of the first shield region 251 is not limited to the hexagonal shape.

In addition, in the unit cells C of an m−1th and/or m+1th column adjacent to the unit cells C of the mth column, the source 230 and the shield region 250 may be opposite or in a mirror image to those of the unit cells of the mth column. That is, the source 230 of the unit cells C of the m−1th and/or m+1th column is referred to as a “second source 233”, and the shield region 250 is referred to as a “second shield region 253”. Here, the second shield region 253 may have, for example, a hexagonal shape in each of the unit cells C and may be spaced apart from the gate electrode 240. The second source 233 may surround the second shield region 251. The second source 231 may have, for example, a hexagonal shape. Thus, a channel region may be in the unit cells C of the m−1th column and/or the m+1th column. However, the shape of the second source 233 is not limited to the hexagonal shape, and the shape of the second shield region 253 is not limited to the hexagonal shape, either.

Here, the m−1th and/or m+1th columns including additional pluralities of unit cells C may be referred to as a “channel-forming region,” and the mth column may be referred to as a “non-channel-forming region.” As described above, when the channel-forming regions and the non-channel-forming regions cross each other, an advantageous structure for electric field distribution may be obtained.

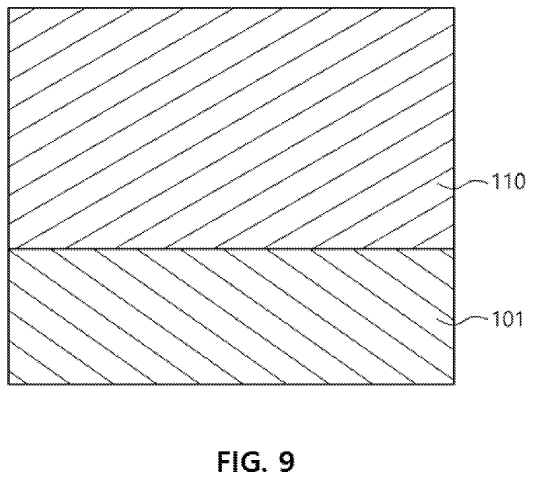

FIGS. 9 to 17 are cross-sectional views illustrating a method of manufacturing a SiC MOSFET power semiconductor device according to one or more embodiments of the present disclosure.

Hereinafter, the method of manufacturing the SiC MOSFET power semiconductor device according to the present disclosure will be described in detail with reference to the accompanying drawings. It should be noted that the sequence of the steps of the manufacturing method is not limited to the order described below.

Referring to FIG. 9, first, a drift region 110 may be formed on a substrate 101. The drift region 110 may be formed by epitaxial growth on the substrate 101 (which may comprise crystalline SiC, at least at an uppermost surface thereof). The drift region 110 may also be formed by, for example, chemical vapor deposition (CVD), but is not limited thereto, and may be formed by various processes such as molecular beam epitaxy (MBE), sublimation epitaxy, and liquid phase epitaxy.

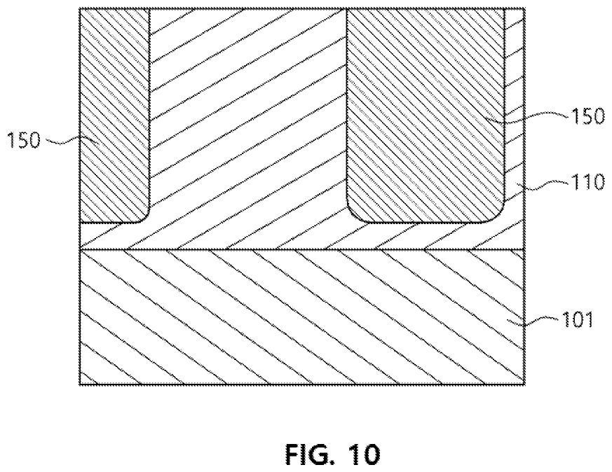

Then, referring to FIG. 10, a shield region 150 may be formed in the drift region 110. The shield region 150 may be formed by ion implantation using a first conductivity type impurity implanted through a mask pattern (not illustrated) into the uppermost surface of the drift region 110. As described above, the shield region 150 may comprise a heavily doped first conductivity type impurity region.

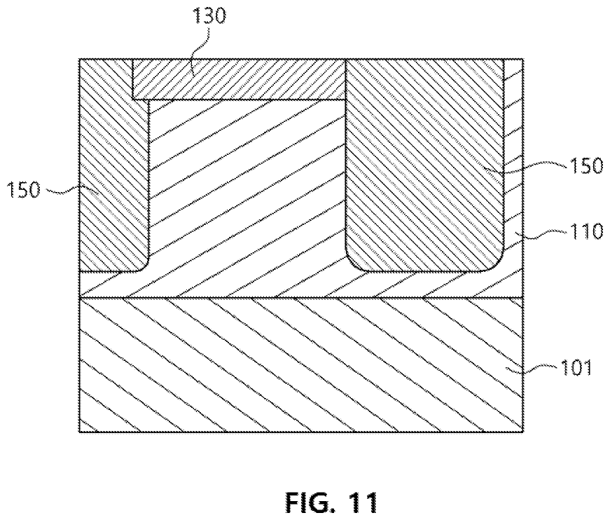

Then, referring to FIG. 11, a source 130 may be formed in the surface of the drift region 110. The source 130 may be formed by ion implantation using a second conductivity type impurity implanted through a different and/or corresponding mask pattern (not illustrated) into the uppermost surface of the drift region 110. The source 130 may overlap or contact one or more adjacent shield regions 150. As described above, the source 130 may comprise a heavily doped second conductivity type impurity region.

In the device 1 according to the first embodiment, the source 130 and the shield region 150 may cross each other (see FIG. 1). In the device 2 according to the second embodiment, the source 230 and the shield region 250 may have a plurality of different structures or configurations (e.g., mirror image configurations), depending on whether they are in the mth column or the m−1th or m+1th column (see FIG. 5). Different shapes of the sources 130 and 230 and the shield regions 150 and 250 may be implemented using different mask patterns, and a detailed description thereof will be omitted.

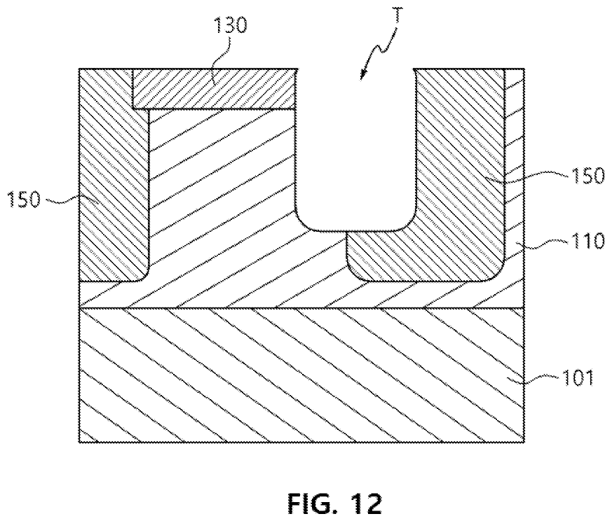

Then, referring to FIG. 12, a trench T may be formed in the drift region 110. The trench T may be formed by etching the drift region 110 using a mask pattern (not illustrated) exposing the area(s) to be etched, and may have, for example, a honeycomb pattern or structure with a hexagonal shape.

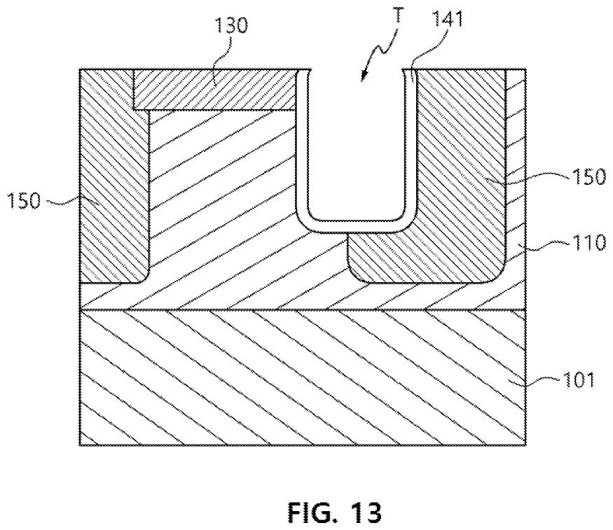

Then, referring to FIG. 13, a gate oxide film 141 may be formed in the trench T. The gate oxide film 141 may be formed by depositing an oxide film or layer (e.g., silicon dioxide) on the source 130 and the shield region 150 and along an inner surface of the trench T (e.g., by chemical vapor deposition [CVD] using a precursor gas such as tetraethyl orthosilicate [TEOS] or silane [SiH₄] in the presence of oxygen) and then etching the oxide film or layer on the source 130 and the shield region 150 to remove it therefrom. Alternatively, the oxide film or layer may be removed from the source region 130 and the shield region 150 by polishing (e.g., chemical mechanical polishing [CMP]).

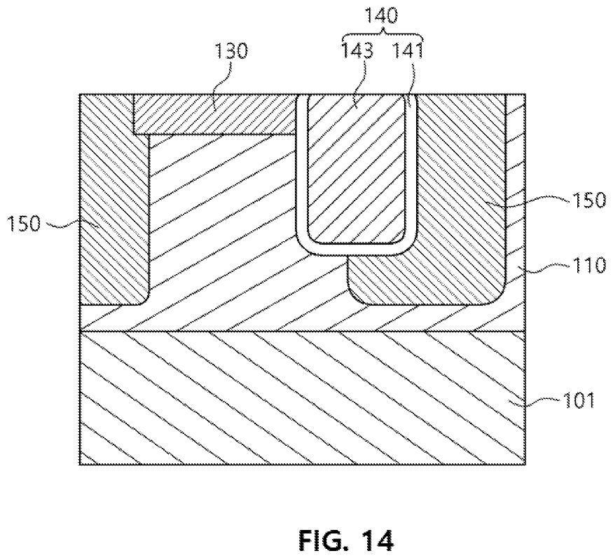

Then, referring to FIG. 14, a gate electrode 143 may be formed on the gate oxide film 141 and filling the trench T. The gate electrode 143 may be formed by blanket-depositing a polysilicon film (e.g., by CVD, physical vapor deposition [PVD], etc.; not illustrated) on the source 130 and the shield region 150 and filling the trench T, and then etching the polysilicon film using a mask pattern (not illustrated). Alternatively, the polysilicon film can be removed from the source region 130 and the shield region 150 by polishing (e.g., CMP).

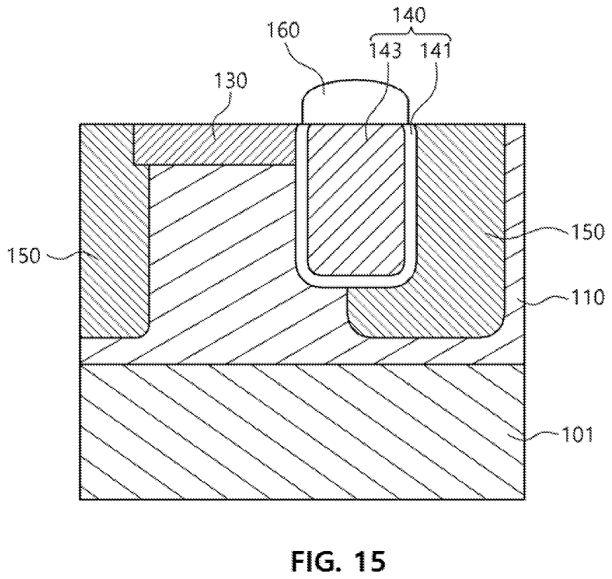

Then, referring to FIG. 15, an insulating film 160 may be formed on the gate region 140. The insulating film 160 may be formed by blanket-depositing an insulating film or layer (e.g., an oxide film or layer, such as silicon dioxide) on the source 130, the shield region 150, and the gate region 140 as described herein, and then performing an etching process (e.g., using an etching mask, which may comprise a photolithographically-patterned photoresist; not shown).

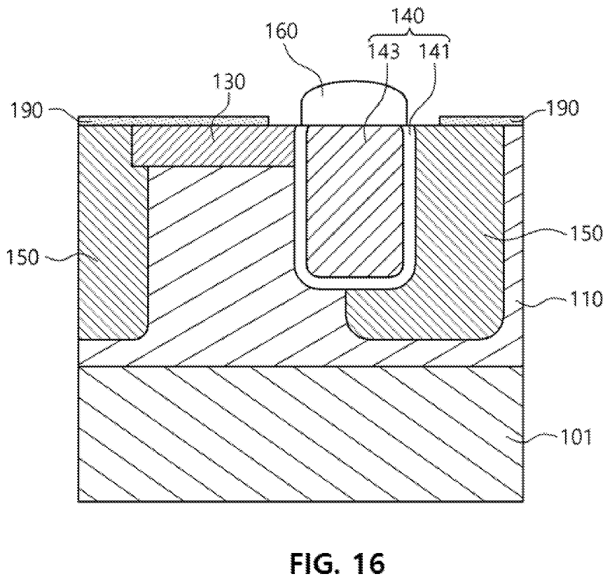

Then, referring to FIG. 16, an ohmic contact 190 may be formed on the source 130 and the shield region 150. The ohmic contact 190 may be formed by blanket-depositing Ti or TiN (e.g., by CVD or sputtering), onto the source 130, the shield region 150, and the gate region 140, then etching the deposited Ti or TiN using a patterned photoresist as a mask.

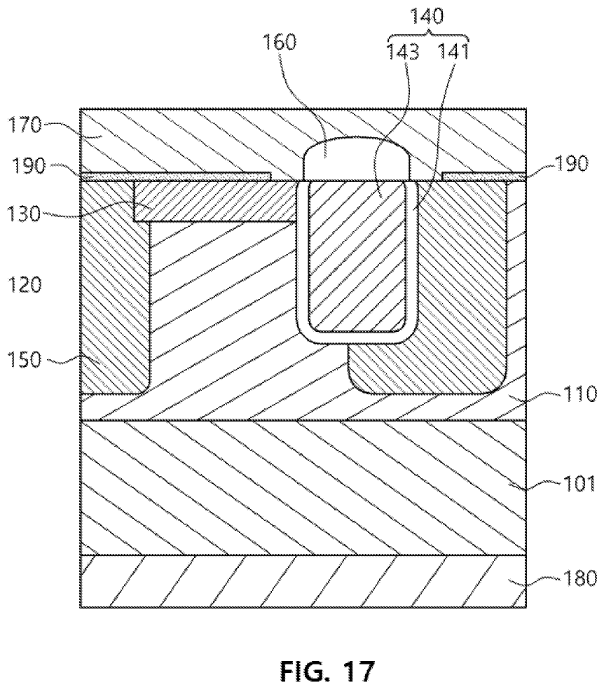

Then, referring to FIG. 17, a source metal or source electrode 170 may be formed on the source 130, the shield region 150, and the insulating film 160 by depositing a metal layer comprising Al or a conductive Al alloy onto the structure of FIG. 16. The source metal or source electrode 170 may be planarized by conventional etchback or CMP. Finally, the drain metal or drain electrode 180 may be formed by blanket-depositing a metal layer such as a Ni and/or Ag layer on a lower surface of the substrate 101 (e.g., by sputtering, CVD, evaporation, etc.).

The foregoing detailed description may be merely an example of the present disclosure. Also, the inventive concept is explained by describing various embodiments and will be used through various combinations, modifications, and environments. That is, the inventive concept may be amended or modified without departing from the scope of the technical idea and/or knowledge in the art. The foregoing embodiments illustrate various modes for implementing the technical idea of the present disclosure, and various modifications may be made therein according to specific application fields and uses thereof. Therefore, the foregoing detailed description of the present disclosure is not intended to limit the inventive concept to the disclosed embodiments.

What is claimed is:

1. A SiC MOSFET power semiconductor device comprising:
a substrate;
a lightly doped second conductivity type drift region on the substrate;
a first conductivity type well in the drift region;
a heavily doped second conductivity type source in a surface of the well;
a trench gate region of a trench structure having an upper surface substantially coplanar with a surface of the well or the source, and a lowermost surface in the drift region; and
a heavily doped first conductivity type shield region having an upper surface substantially coplanar with the surface of the well and a lowermost surface in the drift region.

2. The SiC MOSFET power semiconductor device of claim 1, wherein the lowermost surface of the shield region is lower than the lowermost surface of the gate region.

3. The SiC MOSFET power semiconductor device of claim 2, wherein the shield region is in contact with a sidewall of the gate region and is in partial contact with the lowermost surface of the gate region.

4. The SiC MOSFET power semiconductor device of claim 1, wherein the gate region has a hexagonal shape and a honeycomb structure.

5. The SiC MOSFET power semiconductor device of claim 4, further comprising an ohmic contact on the shield region and the source.

6. A SiC MOSFET power semiconductor device comprising:
a substrate;
a lightly doped second conductivity type drift region on the substrate;
a trench gate region having a lowermost surface in the drift region, a hexagonal shape, and a honeycomb structure, and separating a plurality of unit cells of substantially the same area;
a heavily doped second conductivity type source in contact with the trench gate region and in each of the unit cells; and
a heavily doped first conductivity type shield region having a lowermost surface in the drift region lower than the lowermost surface of the trench gate region,
wherein the source and the shield region in each of the unit cells are alternately arranged along a hexagonal path around a center of the unit cell at a position a predetermined distance from the center.

7. The SiC MOSFET power semiconductor device of claim 6, wherein each of the unit cells may comprise a plurality of the sources, and the plurality of the sources are in contact with every other surface of the trench gate region in each of the unit cells.

8. The SiC MOSFET power semiconductor device of claim 7, wherein the plurality of the sources are not continuously in contact with adjacent surfaces of the trench gate region in each of the unit cells.

9. The SiC MOSFET power semiconductor device of claim 6, further comprising:
a first conductivity type well below the source and in or on the drift region;
an insulating film on the trench gate region; and
an ohmic contact on the source and the shield region.

10. The SiC MOSFET power semiconductor device of claim 6, wherein in each of the unit cells, the source and the shield region alternate along the hexagonal path around the center of the unit cell at a position spaced from the center by a distance smaller than a distance from the center to the trench gate region.

11. The SiC MOSFET power semiconductor device of claim 10, wherein in each of the unit cells, the source and the shield region do not alternate around the center of the unit cell at a position adjacent to the center.

12. The SiC MOSFET power semiconductor device of claim 6, wherein the shield region is in contact with at least part of a lower portion of an adjacent gate region.

13. The SiC MOSFET power semiconductor device of claim 11, wherein each pair of adjacent unit cells has the same cross-section between centers thereof.

14. A SiC MOSFET power semiconductor device comprising:
a substrate;
a lightly doped second conductivity type drift region on the substrate; and
a trench gate region having a lowermost surface in the drift region, the trench gate region having a hexagonal shape and a honeycomb structure and separating a plurality of unit cells into n columns,
wherein the unit cells of an mth column are non-channel-forming regions, and the unit cells of an m−1th and/or m+1th column are channel-forming regions.

15. The SiC MOSFET power semiconductor device of claim 14, wherein each of the unit cells of the mth column comprises:
a first heavily doped second conductivity type source spaced apart from an adjacent gate region; and
a first heavily doped first conductivity type shield region between the first source and the adjacent gate region.

16. The SiC MOSFET power semiconductor device of claim 14, wherein each of the unit cells of the m−1th and/or m+1th column comprises:
a second heavily doped first conductivity type shield region spaced apart from the adjacent gate region; and
a second heavily doped second conductivity type source between the second shield region and the adjacent gate region.

17. The SiC MOSFET power semiconductor device of claim 15, wherein the first source has a hexagonal shape, and
the first shield region has a hexagonal shape.

18. A method of manufacturing a SiC MOSFET power semiconductor device, the method comprising:
forming a drift region on a substrate;
forming a shield region in the drift region;
forming a source in the drift region;
forming a trench in the drift region;
forming a gate oxide film in the trench and forming a gate electrode on the gate oxide film and filling the trench;
forming an insulating film on the gate electrode; and
forming an ohmic contact on the source and the shield region,
wherein the trench has a lowermost surface higher than a lowermost surface of the shield region and a honeycomb structure with a hexagonal shape, and the trench separates a plurality of unit cells.

19. The method of claim 18, wherein the source and the shield region in each of the unit cells alternate along a hexagonal path around a center of the unit cell at a position a predetermined distance from the center.

20. The method of claim 18, wherein the trench separates the unit cells into n columns,
the unit cells of an mth column are non-channel-forming regions, and
the unit cells of an m−1th and/or m+1th column are channel-forming regions.
